(19) United States
(12) Patent Application Publication
(10) Pub. No.: US 2010/0213466 A1
(43) Pub. Date: Aug. 26, 2010

(54) PHOTOSENSORS INCLUDING SEMICONDUCTOR-ON-INSULATOR STRUCTURE

(76) Inventors: Karl D. Hirschman, Henrietta, NY (US); Robert Manley, Rochester, NY (US); Carlo Anthony Kosik Williams, Painted Post, NY (US)

Correspondence Address: CORNING INCORPORATED, SP-TI-3-1, CORNING, NY, 14831, US

(21) Appl. No.: 12/393,292

(22) Filed: Feb. 26, 2009

(51) Int. Cl. H01L 33/00; H01L 31/0352; H01L 29/786

(52) U.S. Cl. 257/72; 257/458; 257/80; 257/E31.032; 257/E33.077; 257/E29.273

(57) ABSTRACT

Photosensor based on SOI technology and display devices comprising the same. The photosensor can be a photodiode or a phototransistor, or a combination thereof when incorporated in a device. The photosensor exhibits a higher photoresponse than a traditional photosensor based on amorphous silicon film or polysilicon thin film technology. The present invention is useful, e.g., in making multifunctional display devices having photosensing function integrated therein.

### TECHNICAL FIELD

The present invention relates to photosensors. In particular, the present invention relates to photosensors including a semiconductor-on-insulator structure. The present invention is useful in making, inter alia, LCD display having an integrated sensing function and high-sensitivity photosensing devices.

### BACKGROUND

As used herein, the abbreviation “SiOI” refers to silicon-on-insulator. The abbreviation “SOI” refers to semiconductor-on-insulator in general, including but not limited to SiOI. The abbreviation “SiOG” refers to silicon-on-glass. The abbreviation “SOC” refers to semiconductor-on-glass in general, including but not limited to SiOG. SOG is intended to include semiconductor-on-ceramics and semiconductor-on-glass-ceramics structures. Likewise, SiOG is intended to include silicon-on-ceramics and silicon-on-glass-ceramics structures.

SiOI technology is becoming increasingly important for high performance thin film transistors, solar cells, and displays, such as active matrix displays. The SiOI wafers typically consists of a thin layer of substantially single-crystalline silicon generally 0.1-0.3 microns in thickness but, in some cases, as thick as 5 microns, on an insulating material.

Various ways of obtaining such a SiOI wafer include epitaxial growth of Si on lattice matched substrates; bonding of a single-crystalline wafer to another silicon wafer on which an oxide layer of SiO₂ has been grown, followed by polishing or etching of the top wafer down to, for example, a 0.1 to 0.3 micron layer of single-crystalline silicon; or ion-implantation methods in which either hydrogen or oxygen ions are implanted either to form a buried oxide layer in the silicon wafer topped by Si in the case of oxygen ion implantation or to separate (exfoliate) a thin Si layer to bond to another Si wafer with an oxide layer as in the case of hydrogen ion implantation. Of these three approaches, the approaches based on ion implantation have been found to be more practical commercially. In particular, the hydrogen ion implantation method has an advantage over the oxygen implantation process in that the implantation energies required are less than 50% of that of oxygen ion implants and the dosage required is two orders of magnitude lower.

The hydrogen ion implantation method typically consists of the following steps. A thermal oxide layer is grown on a single-crystalline silicon wafer. Hydrogen ions are then implanted into this wafer to generate subsurface flaws. The implantation energy determines the depth at which the flaws are to be generated and the dosage determines flaw density. This wafer is then placed into contact with another silicon wafer (the support substrate) at room temperature to form a tentative bond.

The wafers are then heat-treated to about 600° C. to cause growth of the subsurface flaws for use in separating a thin layer of silicon from the Si wafer. The resulting assembly is then heated to a temperature above 1000° C. to fully bond the Si film with SiO₂ underlayer to the support substrate, i.e., the un-implanted silicon wafer. This process thus forms a SiOI structure with a thin film of silicon bonded to another silicon wafer with an oxide insulator layer in between.

Cost is an important consideration for commercial applications of SOI and SiOI structures. To date, a major part of the cost of such structures has been the cost of the silicon wafer which supports the oxide layer, topped by the Si thin film, i.e., a major part of the cost has been the support substrate.

It is not at all a simple matter to replace a silicon wafer with a wafer made out of a less expensive material in an SOI structure. In particular, it is difficult to replace a silicon wafer with a glass or glass-ceramic or ceramic of the type which can be manufactured in large quantities at low cost, i.e., it is difficult to make cost effective SOG and SiOG structures.

Co-pending, co-assigned U.S. patent application Ser. No. 10/779,582, published as US2004/0229444 A1, describes techniques for making SiOG and SOG structures and novel forms of such structures. Among the numerous applications for the invention are those in such fields as optoelectronics, FR electronics, and mixed signal (analog/digital) electronics, as well as display applications, e.g., LCDs and OLEDs, where significantly enhanced performance can be achieved compared to amorphous and polysilicon based devices. In addition, photovoltaics and solar cells with high efficiency were also enabled. Both the processing techniques and its novel SOI structures significantly lower the cost of an SO structure.

Another factor significantly affecting the cost of ion-implantation approach to producing SOI, SiOI, SOG and SiOG structures is the efficiency of the ion-implantation process. Traditionally, hydrogen ion implantation or oxygen ion implantation were used, with the former being preferred due to the higher efficiency. However, those traditional ion-implantation processes require the use of narrow ion beams, which lead to long implantation time and high cost. As a result, substitute ion sources were developed and disclosed in the prior art.

Photosensors are devices that produce an output voltage or current response upon absorption of photons. There are many varieties of photosensors that are used in a wide assortment of applications. In recent years, there has been a growing interest to develop photosensors in thin-film semiconductor on an insulating substrate such as display glass. For example, researchers have reported progress in photodiodes implemented in amorphous or polycrystalline thin film silicon on display glass for applications such as optical image sensor, ambient light sensing in mobile application, touch screen panel input for LCD displays, color image scanner embedded in a TFT-LCD array, and all of the aforementioned functionalities. In all these applications that pertain to the integration of photosensor within a pixel display, it should be noted that the instability, poor uniformity, and low dynamic range are problems that are inherent in the amorphous- and/or poly-silicon film used for implementing the sensor and readout electronics. Additionally, in the case where photosensors are embedded in a crystalline SiOI substrate for biosensor applications, the proposed substrate to allow optical access is usually the more expensive sapphire material.

Therefore, there is a need of a cost-effective photosensor having good performance. The present invention satisfies this and other needs by offering a solution using the SOI technology.

### SUMMARY

Several aspects of the present invention are disclosed herein. It is to be understood that these aspects may or may not overlap with one another. Thus, part of one aspect may fall within the scope of another aspect, and vice versa.

Each aspect is illustrated by a number of embodiments, which, in turn, can include one or more specific embodiments. It is to be understood that the embodiments may or may not overlap with each other. Thus, part of one embodiment, or specific embodiments thereof, may or may not fall within the ambit of another embodiment, or specific embodiments thereof, and vice versa.

According to a first aspect of the present invention, provided is a photosensor comprising a glass substrate, a layer of single-crystalline semiconducting material anodically bonded to a surface of the glass substrate, and a photosensitive device built on the surface comprising in part of the semiconducting material.

In a first embodiment of the photosensor according to the first aspect of the present invention, the single-crystalline semiconducting layer has a thickness of at least 100 nm (e.g., for integration into active matrix liquid crystal or organic light emitting diode (AMLCD or AMOLED) display pixels with fully depleted transistor operation), in certain embodiments at least 200 nm (e.g., for integration with display pixels with partially depleted transistor operation, and at least 1000 nm for other embodiments).

In a second embodiment of the photosensor according to the first aspect of the present invention, the single-crystalline semiconducting layer consists essentially of single-crystalline silicon.

In a third embodiment of the photosensor according to the first aspect of the present invention, the photosensor comprises a photodiode or a phototransistor, or a combination thereof.

In a fourth embodiment of the photosensor according to the first aspect of the present invention, the photo sensor comprises a photodiode having a p-i-n structure.

In a fifth embodiment of the photosensor according to the first aspect of the present invention, the photosensor exhibits a photo-response efficiency with respect to red light at 660 nm of at least 0.5, in certain embodiments at least 0.8, in certain embodiments at least 1.0, in certain embodiments at least 1.2, in certain embodiments at least 1.5, in certain embodiments at least 1.8, in certain embodiments at least 2.0.

In a sixth embodiment of the photosensor according to the first aspect of the present invention, the photosenor exhibits a photo-response efficiency with respect to green light at 570 nm of at least 2.0, in certain embodiments at least 2.5, in certain embodiments at least 3.0, in certain embodiments at least 3.5, in certain embodiments at least 4.0.

In a seventh embodiment of the photosensor according to the first aspect of the present invention, the photosenor exhibits a photo-response efficiency with respect to blue light at 462 nm of at least 10, in certain embodiments at least 12, in certain embodiments at least 12, in certain embodiments at least 14, in certain other embodiments at least 16, in certain embodiments at least 18.

According to a second aspect of the present invention, provided is a display device comprising a glass substrate, a layer of single-crystalline semiconductor material anodically bonded to at least one surface of the glass substrate, and a plurality of semiconductor components comprising the single-crystalline material, wherein the plurality of semiconductor components include a photosensor.

In a first embodiment of the display device according to the second aspect of the present invention, the plurality of semiconductor components further include a plurality of thin-film-transistors.

In a second embodiment of the display device according to the second aspect of the present invention, the photosensor and the thin-film-transistors are electrically connected such that the output of the photosensor controls the output of at least one of the thin-film-transistors.

In a third embodiment of the display device according to the second aspect of the present invention, the devices comprises a plurality of the photosensors, which collectively function as an image sensor array.

In a fourth embodiment of the display device according to the second aspect of the present invention, the photosensor comprises a photodiode, a phototransistor, or a combination thereof.

One or more embodiments of one or more aspects of the present invention have one or more of the following advantages. First, the photosensors based on SOI structures bearing a single-crystalline semiconductor layer, especially on SiOG bearing a layer of single-crystalline silicon, has a high photo-response. Second, the photosensors can be integrated into a single glass substrate along with other electrical components, making it possible to make a complex, multifunctional device based on a single glass substrate. Third, both photosensor of the photodiode type and phototransistor type, especially those based on SiOG structures comprising a layer of single-crystalline silicon, can be very stable (negligible degradation over time), good photosensitivity, and uniform device-to-device performance over a large area. Fourth, the photosensors can have a larger dynamic range than those based on armorphous or polycrystalline silicon. The dynamic range is the ability of the photosensor to have a linear response over a wider range of incident light intensity. This would allow for greater color resolution.

Additional features and advantages of the invention will be set forth in the detailed description which follows, and in part will be readily apparent to those skilled in the art from the description or recognized by practicing the invention as described in the written description and claims hereof as well as the appended drawings.

It is to be understood that the foregoing general description and the following detailed description are merely exemplary of the invention, and are intended to provide an overview or framework to understanding the nature and character of the invention as it is claimed.

The accompanying drawings are included to provide a further understanding of the invention, and are incorporated in and constitute a part of this specification.

### BRIEF DESCRIPTION OF THE DRAWINGS

In the accompanying drawings:

FIG. 1 is a schematic illustration of the layered structure of a p-i-n photodiode based on SiOG substrate comprising a layer of single-crystalline silicon according to one embodiment of the present invention.

FIG. 2 is a diagram showing the typical current-voltage characteristics in the reverse bias region of the p-i-n photodiode showing the low dark current and about 15 nA response to white light illumination.

FIG. 3 is a diagram showing simulated transfer characteristics of a thin-film n-type photo-TFT at various light intensities. The transistors were illuminated with a simulated beam of light with a wavelength spectrum between 400 nm and 800 nm, all at equal intensities. The transistor was uniformly illuminated.

FIG. 4 is a diagram showing simulated transfer characteristics of a thin-film p-type photo-TFT at various light intensities. The transistors were illuminated with a simulated beam of light with a wavelength spectrum between 400 nm and 800 nm, all at equal intensities. The transistor was uniformly illuminated.

### DETAILED DESCRIPTION

Unless otherwise indicated, all numbers such as those expressing weight percents of ingredients, dimensions, and values for certain physical properties used in the specification and claims are to be understood as being modified in all instances by the term “about.” It should also be understood that the precise numerical values used in the specification and claims form additional embodiments of the invention. Efforts have been made to ensure the accuracy of the numerical values disclosed in the Examples. Any measured numerical value, however, can inherently contain certain errors resulting from the standard deviation found in its respective measuring technique.

As used herein, in describing and claiming the present invention, the use of the indefinite article “a” or “an” means “at least one,” and should not be limited to “only one” unless explicitly indicated to the contrary. Thus, for example, “a photosensor” includes embodiments having two or more such photosensors, unless the context clearly indicates otherwise.

SOI technology and, especially SiOG technology, involving the transfer of a layer of single-crystalline semiconductor material such as silicon has been disclosed in commonly-assigned U.S. patent application Ser. No. 10/779,582 (published as US2004/0229444 A) and Ser. No. 11/444,741 (published as US2007/0281399 A1), the relevant parts thereof are incorporated herein by reference in their entirety. The SOI structures and the processes of making disclosed in these references can be utilized to make the photosensors according to the present disclosure.

The process of the SOI technology as disclosed in these commonly-assigned patent applications result in an insulator substrate, such as a glass substrate, bearing a layer of single-crystalline semiconductor material. The technology can be chosen to make a SiOG structure or other types of SOI structure having a single crystalline layer having a thickness of at least 100 nm, in certain embodiments at least 200 nm, in certain embodiments at least 400 nm, in certain embodiments at least 600 nm, in certain embodiments at least 800 nm, in certain embodiments at least 1000 nm, in certain embodiments at least 1200 nm. Specifically, in the process of making silicon-on-glass structures using ion implantation, the energy of the ion can be chosen such that the exfoliated single-crystal silicon layer at various thickness can be transferred to the surface of the glass substrate and bonded to the glass surface anodically. A thickness up to 200 nm can be advantageously used for realizing photosensors integrated within display module pixels. Thickness up to 1200 nm can be realized for SiOG substrates which would allow for the fabrication of photosensors with substantially higher photoresponse efficiencies.

As used herein, the term “single-crystalline” means that the corresponding semiconducting material has the main structure of a single-crystalline material, with or without defects and dopants intentionally or unintentionally included therein. Thus, a doped p-type single-crystalline silicon or germanium or n-type single-crystalline silicon or germanium would be considered single-crystalline in the present disclosure.

As discussed supra, traditional photosensors based on amorphous silicon and polysilicon technology suffer from various technical issues.

To address the above concerns, photosensors based on SOI (SiOG, in particular) structures have been made and are now disclosed herein.

Photosensors based on SiOG structures comprising a layer of single-crystalline silicon have been made and characterized. It is to be understood that, however, one having ordinary skill in the art, based on the teachings of the present disclosure and the various patent literatures mentioned supra, can make photosensors based on other SOI structures comprising a layer of single-crystalline semiconducting materials. For example, Ge-on-glass structures, Si-on-glass-ceramic, Si-on-ceramic, and other structures can be fabricated and used as the basis for making the photosensors according to the present disclosure.

In certain embodiments of the photosensor of the present disclosure, the photosensor comprises a photodiode. In certain other embodiments, the photosensor comprises a phototransistor. In certain embodiments of the device according to the present disclosure, the device comprises a plurality of photosensors, which can be photodiodes, phototransistors and combinations thereof. The embodiments include a photo-transistor and a lateral p-i-n photodiode structure.

Both photosensor of the photodiode type and phototransistor types, especially those based on SiOG structures comprising a layer of single-crystalline silicon, can be very stable (negligible degradation over time), good photosensitivity, and uniform device-to-device performance over a large area.

Thus, in various embodiments of photosensors according to the present disclosure, one or more of the following fabrication routes can be adopted to achieve various technical objectives.

In one embodiment, a photo-TFT employing a transparent metal-oxide-semiconductor as the sensor area whereby the oxide-semiconductor interface traps incident light more effectively for increased photo-response efficiency even for red light, can be made.

In another embodiment, a photo-TFT with transparent gate-metal where the bias can be adjusted to allow for optimum photosensitivity or to achieve uniform performance from one device to another, can be made.

In another embodiment, a p-i-n photodiode employing an oxide-semiconductor as the sensor area whereby the oxide-semiconductor interface traps incident light more effectively for increased photo-response efficiency even for red light, can be made.

In another embodiment, a lateral diode for both the photo-TFT and the p-i-n photodiode that allows for increased area for photo-capture (electron-hole generation) to occur and allow for improved photo-response efficiency, can be made.

In another embodiment, a thin-film photo-TFT or a p-i-n photodiode that responds to the full spectra of blue, green, and red light, can be made.

In another embodiment, a thin-film photo-TFT or a p-i-n photodiode that offers higher dynamic range relative to amorphous- and poly-silicon, can be made.

In another embodiment, a thin-film photo-TFT or a p-i-n photodiode with lower performance variations between close and long range photosensors relative to poly-silicon based photosensors, can be made.

In another embodiment, a thin-film photo-TFT or p-i-n photodiode with improved stability—negligible photosensor degradation over time relative to amorphous-silicon based photosensors, can be made.

In certain embodiments, fabrication processes having low complexity, low temperature that translates to minimal impact on manufacturing yield for display applications, can be utilized.

In a non-limiting, exemplary embodiment of making a substrate bearing an anodically bonded single-crystalline semiconductor material (such as a single-crystalline silicon), a single-crystalline silicon wafer is first implanted with hydrogen ions to create a buried defect layer at a known depth within the bulk wafer. The wafer is then brought into contact with the surface of a glass substrate, such as Corning EAGLE2000® glass for LCD displays, and then heated. Simultaneous application of voltage to the glass and the silicon wafer causes the silicon to anodically bond firmly to the glass, while the heat and differential CTE cause the hydrogen defect layer to cleave. The final result is a thin film of single crystal silicon bonded to the glass to create the SiOG substrate.

The SiOG substrate that is then subjected to the device fabrication process to fabricate the photosensors according to the present disclosure, such as a photo-transistor or a p-i-n photodiode.

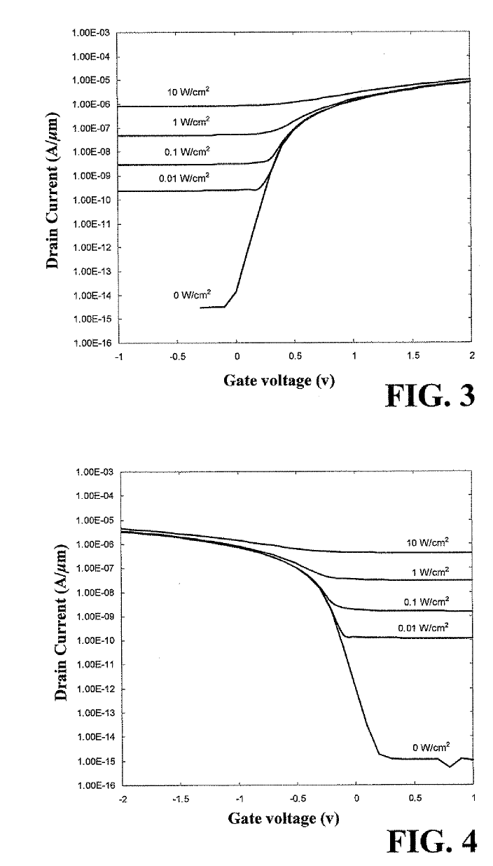

In the case of the photo-transistor, the fabrication process is a modification of the low temperature, low complexity fabrication process for making high quality n- and p-type TFTs. The photo-transistor fabrication makes use of a transparent gate electrode, such as indium tin oxide (ITO), exposing the channel region of the TFT to incident light. The light incident in the channel region of the transistor causes generation of electron-hole pairs that lead to a conductivity change across the channel. This conductivity change is essentially a modulation of the TFT transconductance that manifests itself in an increase current. FIGS. 3 and 4 show shows simulated transfer characteristics of a thin-film n-type (FIG. 3) and p-type (FIG. 4) photo-TFT at various light intensities. With no incident light, the I-V curves for both photo-TFT types exhibit the low off-current behavior that is expected of a traditional TFT. With exposure to increasing intensities of white light, the off-current increases accordingly due to the excess photo-current generated from the absorption of the light in the channel region.

In the case of the p-i-n photodiode, the fabrication is a simplified version of the photo-TFT where no gate electrode is included atop the oxide.

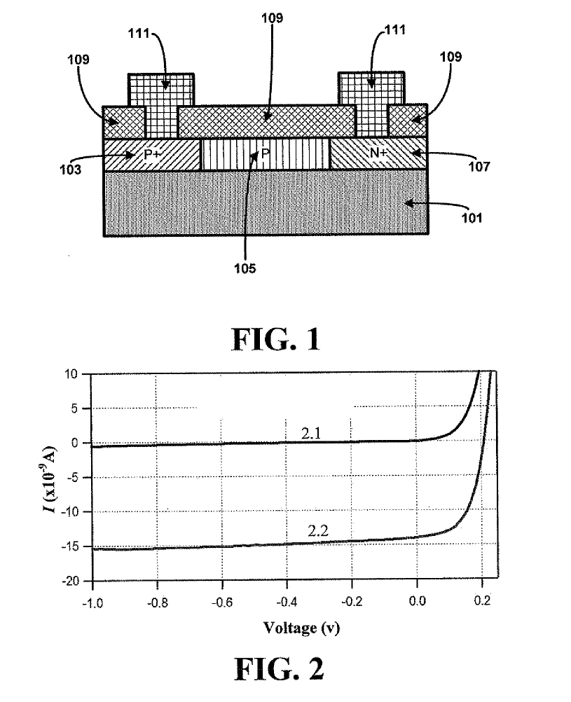

FIG. 1 schematically illustrates a layered structure of a p-i-n type photodiode according to one embodiment of the present disclosure that was fabricated and tested. In this figure, 101 is a aluminosilicate glass substrate having a thickness of about 650 μm. A layer of single-crystalline silicon was anodically bonded to a surface of the glass substrate 101. The layer was then differentially doped to form a p⁺-area 103, a p-area 105, and an n⁺-area 107. The layer comprising 103, 105 and 107 has a thickness of about 200 nm. Above the silicon layer, a SiO₂ insulator layer 109 was then formed and etched. The 109 layer can be about 450 nm. Aluminum electrodes 111, with a thickness above the SiO₂ layer of about 750 μm, were finally formed over the etched SiO₂ layer.

According to the second aspect of the present disclosure, the photosensors according to the first aspect of the present disclosure is incorporated into a display device comprising a glass substrate, a layer of single-crystalline semiconductor material anodically bonded to at least one surface of the glass substrate, and a plurality of semiconductor components comprising the single-crystalline material, wherein the plurality of semiconductor components include a photosensor according to the first aspect of the present invention.

In one embodiment, the display device is a TFT display. The TFT display can be a LCD display.

In one embodiment, the photosensors and the TFT transistors are electrically connected on a single glass substrate, and the output of the photosensors is used to control at least part of the TFT transistors, which, in turn, control other components in the display device.

In another embodiment, the display device comprises a plurality of photosensors that form an array collectively functioning as an image sensor. Such structure would enable a multi-functional device capable of displaying and capturing different images simultaneously or at different times.

In FIG. 2, shown is the current-voltage profile of the p-i-n photodiode illustrated in FIG. 1 in the reverse bias region with a low dark current (2.1) and approximately 15 nA response to white light illumination (2.2).

To quantify the photo-response of the p-i-n photodiode, a blue, green and red diode with fully characterized output power was focused onto the p-i-n sensor and the output current was recorded. Table 1 summarizes the results, showing about 18%, 4% and 2% photo-response efficiency to blue, green, and red light, respectively. The fact that this p-i-n photodiode with 200 nm thick silicon film responds to green and red light is attributed, in part, to the light trapping due to delta index reflections at the oxide-silicon interface as well as to the lateral design that allows for a larger area for increased electron-hole generation to occur. It should be noted that this green/red photo-response capability in thin-film silicon extends to the photo-TFT discussed earlier.

Measured photo-response efficiencies of the SiOG p-i-n photodiodes are provided in TABLE I below.

TABLE I

| | Light color | | |
|---|---|---|---|
| | Red | Green | Blue |
| | (660 nm) | (570 nm) | (462 nm) |
| Photo-response efficiency (%) | 1.8 | 4.2 | 17.7 |

It will be apparent to those skilled in the art that various modifications and alterations can be made to the present invention without departing from the scope and spirit of the invention. Thus, it is intended that the present invention cover the modifications and variations of this invention provided they come within the scope of the appended claims and their equivalents.

What is claimed is:

1. A photosensor comprising a glass substrate, a layer of single-crystalline semiconducting material anodically bonded to a surface of the glass substrate, and a photosensitive device built on the surface comprising in part of the semiconducting material.

2. A photosensor according to claim 1, wherein the single-crystalline semiconducting layer has a thickness of at least 100 nm.

3. A photosensor according to claim 1, wherein the single-crystalline semiconducting layer consists essentially of single-crystalline silicon.

4. A photosensor according to claim 1, which comprises a photodiode or a phototransistor, or a combination thereof.

5. A photosensor according to claim 1, comprising a photodiode having a p-i-n structure.

6. A photosensor according to claim 1, having a photo-response efficiency at 660 nm of at least 0.5.

7. A photosensor according to claim 1, having a photo-response efficiency at 570 nm of at least 2.0.

8. A photosensor according to claim 1, having a photo-response efficiency at 462 nm of at least 10.

9. A display device comprising a glass substrate, a layer of single-crystalline semiconductor material anodically bonded to at least one surface of the glass substrate, and a plurality of semiconductor components comprising the single-crystalline material, wherein the plurality of semiconductor components include a photosensor.

10. A display device according to claim 9, wherein the plurality of semiconductor components further include a plurality of thin-film-transistors.

11. A display device according to claim 9, wherein the photosensor and the thin-film-transistors are electrically connected such that the output of the photosensor controls the output of at least one of the thin-film-transistors.

12. A display device according to claim 9, comprising a plurality of the photosensors, which collectively function as an image sensor array.

13. A display device according to claim 9, wherein the photosensor comprises a photodiode, a phototransistor, or a combination thereof.
